(19) United States
(12) Patent Application Publication
(10) Pub. No.: US 2025/0210363 A1
(43) Pub. Date: Jun. 26, 2025

(54) FAST ATOMIC LAYER ETCH

(71) Applicant: Lam Research Corporation, Fremont, CA (US)

(72) Inventors: Wenbing YANG, Campbell, CA (US); Samantha SiamHwa TAN, Newark, CA (US); Yang PAN, Los Altos, CA (US); Yiwen FAN, Fremont, CA (US); Alexander Declan BENNET, San Jose, CA (US); Arunima Deya BALAN, Mountain View, CA (US); Roger PATRICK, Mountain View, CA (US); Patrick August VAN CLEEMPUT, Castle Rock, WA (US); Derek WITKOWICKI, San Jose, CA (US); Baichang LI, San Jose, CA (US); Young Ah LEE, Fremont, CA (US); Clint Edward THOMAS, Timnath, CO (US)

(21) Appl. No.: 18/846,229

(22) PCT Filed: Mar. 3, 2023
(86) PCT No.: PCT/US2023/014520

§ 371 Date: Sep. 11, 2024

Related U.S. Application Data
(60) Provisional application No. 63/322,535, filed on Mar. 22, 2022.

(51) Int. Cl. H01L 21/3065; H01J 37/32; H01L 21/311

(52) U.S. Cl. CPC H01L 21/3065; H01J 37/32146; H01J 37/32449; H01L 21/31116; H01J 2237/3346

(57) ABSTRACT

A method for etching an etch layer is provided. The method comprises a plurality of cycles, wherein each cycle, comprises exposing the etch layer to neutral radicals for a time between 10 ms and 600 ms, wherein the neutral radicals are absorbed into the etch layer to form a modified part of the etch layer and exposing the etch layer to bombardment ions for a time between 10 ms and 600 ms, wherein the bombardment ions remove the modified part of the etch layer.

### CROSS-REFERENCE TO RELATED APPLICATION

This application claims the benefit of priority of U.S. Application No. 63/322,535, filed Mar. 22, 2022, which is incorporated herein by reference for all purposes.

### BACKGROUND

The background description provided here is for the purpose of generally presenting the context of the present disclosure. Anything described in this background section, and potentially aspects of the written description, are not expressly or impliedly admitted as prior art with respect to the present application.

The disclosure relates to a method of forming semiconductor devices on a semiconductor wafer. More specifically, the disclosure relates to the selective etching of semiconductor devices.

In the formation of semiconductor devices, various layers may be selectively etched. Atomic layer etching may be used to provide an etch with high selectivity. Because an atomic layer etch may remove a monolayer for each cycle, atomic layer etch speed is dependent on the period of each cycle.

Atomic layer etching processes are described in U.S. Pat. No. 10,566,212, entitled “Designer Atomic Layer Etching,” by Kanarik, issued Feb. 18, 2020, U.S. Pat. No. 10,763,083, entitled “High Energy Atomic Layer Etching,” by Yang et al., issued Sep. 1, 2020, US 2021/0005425A1, entitled “Atomic Layer Etching and Smoothing of Refractory Metals and Other High Surface Binding Energy Materials,” by Yang et al., published Jan. 2, 2021, and WO 2020/223152A1, entitled “Atomic Layer Etching for Subtractive Metal Etch,” by Yang et al., published on Nov. 5, 2020, which are all incorporated by references for all purposes.

### SUMMARY

To achieve the foregoing and in accordance with the purpose of the present disclosure, a method for etching an etch layer is provided. The method comprises a plurality of cycles, wherein each cycle, comprises exposing the etch layer to neutral radicals for a time between 10 ms and 600 ms, wherein the neutral radicals are absorbed into the etch layer to form a modified part of the etch layer and exposing the etch layer to bombardment ions for a time between 10 ms and 600 ms, wherein the bombardment ions remove the modified part of the etch layer.

In another manifestation, an etching system for etching an etch layer over a substrate, the etching system is provided. A substrate support supports a substrate in a processing chamber. An RF power source provides RF power to etch chamber. A neutral radical source is adapted to provide neutral radicals in the processing chamber. A bombardment gas source is adapted to provide bombardment gas in the processing chamber. A controller is controllably connected to the RF power source, the neutral radical source, and the bombardment gas source. The controller is configured to expose the etch layer to neutral radicals for a time between 10 ms and 600 ms, wherein the neutral radicals are absorbed into the etch layer to form a modified part of the etch layer and expose the etch layer to bombardment ions for a time between 10 ms and 600 ms, wherein the bombardment ions remove the modified part of the etch layer.

These and other features of the present disclosure will be described in more detail below in the detailed description and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a high level flow chart according to some embodiments.

FIGS. 2A-C are schematic cross-sectional views of an example stack processed according to some embodiments.

FIGS. 3A-C are detailed schematic views of an example etch layer processed according to some embodiments.

FIG. 4 is a cross-sectional side view of an example etch layer that has been processed according to an embodiment.

FIG. 5 is a schematic view of an exemplary plasma processing chamber that may be used in some embodiments.

FIG. 6 is a schematic view of an example computer system that may be used in practicing some embodiments.

### DETAILED DESCRIPTION OF THE PREFERRED EMBODIMENTS

The present disclosure will now be described in detail with reference to a few preferred embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well known process steps and/or structures have not been described in detail in order to not unnecessarily obscure the present disclosure.

In the formation of semiconductor devices, various layers may be selectively etched. Atomic layer etching may be used to provide an etch with high selectivity. In an atomic layer etch (ALE), a cyclical process is provided. The cyclical process may have a first step of modifying part of an etch layer and a second step of removing the modified part of the etch layer. Such an ALE may use a self-limiting process to modify part of the etch layer. The self-limiting process may modify a few monolayers of the etch layer forming a self-limiting layer. In such a case, the removing of the modified part of the etch layer may remove just a monolayer of the etch layer. As a result, many cycles are needed in order to etch a substantial part of the etch layer. Each cycle may be more than 12 seconds long. As a result, an ALE process may take a long time in order to etch a substantial part of an etch layer.

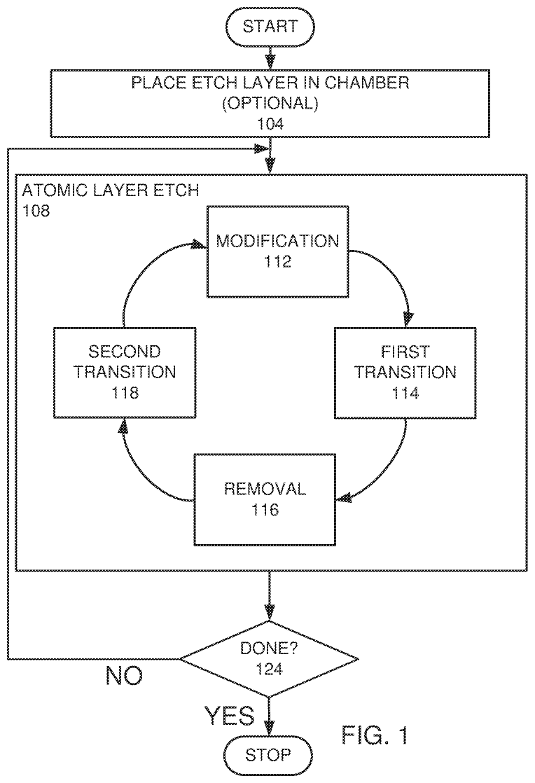

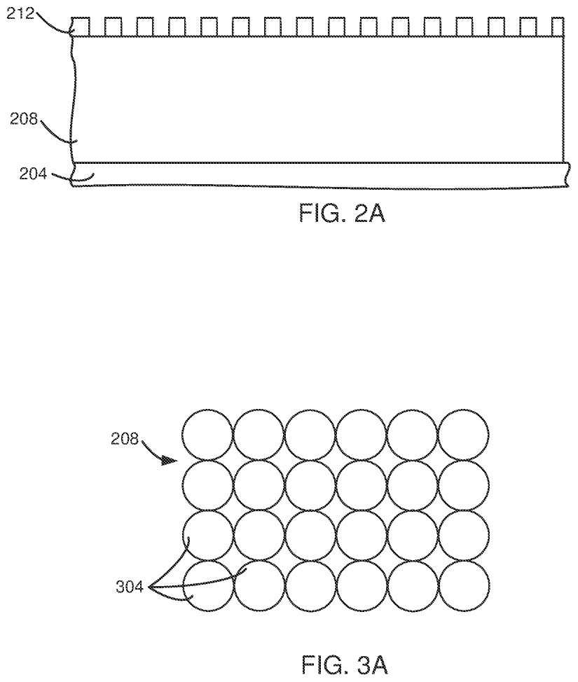

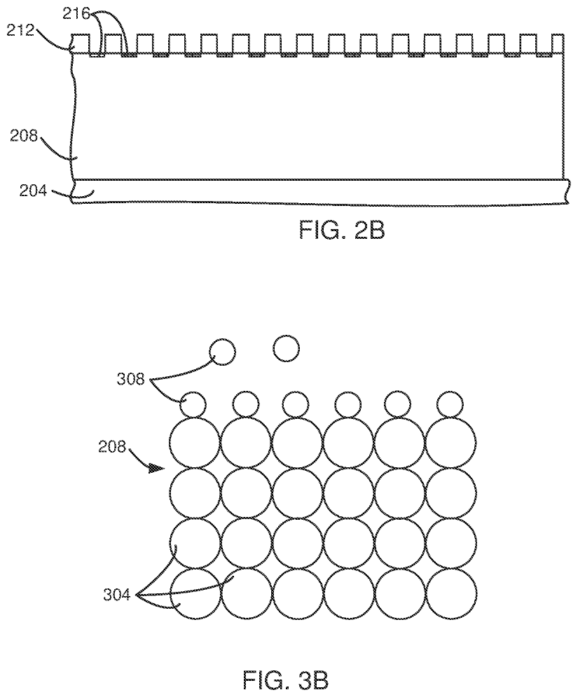

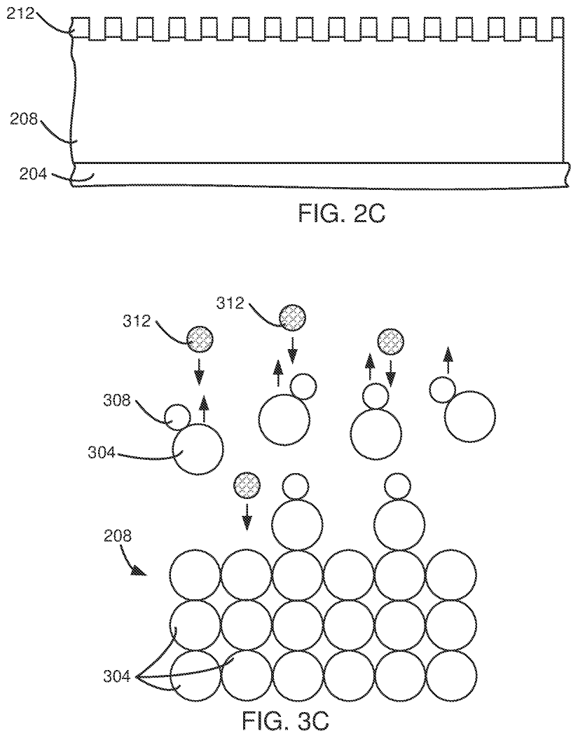

To facilitate understanding, FIG. 1 is a high level flow chart illustrating processes used in some embodiments. As shown, an etch layer over a substrate and under a mask is placed in a processing chamber (step 104). FIG. 2A is a schematic cross-sectional view of an example wafer 204 under an etch layer 208 disposed below a mask 212. In some embodiments, the etch layer 208 is silicon and the photoresist mask 212 is a polymer containing photoresist mask 212. In various embodiments, the photoresist mask may be formed from one or more of extreme ultraviolet (EUV) photoresist, metal-containing photoresist, organometallic photoresist, tin-containing photoresist, tin-oxide containing photoresist, and organotin photoresist. In other embodiments, the mask may not be made of a photoresist material. FIG. 3A is a schematic view of an enlarged section of an exposed portion of the etch layer 208 showing atoms 304 therein.

The etch layer 208 is etched using an atomic layer etch (step 108). The atomic layer etch (step 108) is a cyclical process where in each cycle an exposed surface of the etch layer 208 is modified (step 112). The modification gas is transformed into neutral radicals. The neutral radicals may be created by forming a plasma from the modification gas. In some embodiments, the plasma is formed by providing more than 2000 Watts of RF power at 13.56 megahertz (MHz). In some embodiments, a pressure of between 10 mTorr and 500 mTorr is provided. For example, a pressure of about 35 mTorr may be provided. A higher pressure increases the number of ions that are transformed into neutral radicals. An electric charge may be used to repel ions from the etch layer 208. In some embodiments where a bias is provided, the bias may be less than 50 eV. In other embodiments, a bias may not be provided during the surface modification (step 112). If a bias is provided, the bias may either be pulsed or continuous. If a pulsed bias is provided, the pulsed bias may have a duty cycle of greater than 10% in order to decrease the time needed for the surface modification (step 112). The duty cycle may be adjusted to increase neutral radicals and decrease ions. In some embodiments, this surface modification (step 112) is provided for less than 0.5 seconds(s). In some embodiments, the surface modification is provided for a time between 10 milliseconds (ms) and 600 ms. In other embodiments, the surface modification is provided for a time between 50 ms and 300 ms. In various embodiments, various methods may be used to suppress ions from reaching the etch layer 208. In some embodiments, the flux of neutral radicals near the exposed etch layer is greater than 1018 neutral radicals per centimeters (cm) square per second s (/cm²s). In various embodiments, the flux of the neutral radicals is between about 10¹⁷ to 1020 neutral radicals/cm²s. A higher flux of neutral radicals helps to reduce the time needed for the modification step. The higher flux of neutral radicals can be provided by using one or more of higher pressure, higher RF power, and/or a higher flow rate, as well as possibly other factors.

FIG. 2B is a schematic cross-sectional view of an example wafer 204 under the etch layer 208 disposed below the mask 212 after an exposed portion of the etch layer 208 has been modified. The modified portion is schematically illustrated by the shaded regions 216. The shaded regions 216 are not drawn to scale in order to facilitate understanding since, in this example, a few atomic layers are modified. In various embodiments, from about 1 to 30 atomic or molecular layers are modified. FIG. 3B is a schematic view of an enlarged section of an exposed portion of the etch layer 208 after part of the exposed portion of the etch layer 208 has been modified. Some of the neutral radical atoms 308 form bonds with exposed atoms 304.

After the modification (step 112), a first transition is provided (step 114). The first transition removes the modification gas and provides a bombardment gas (also called a removal gas). In some embodiments, the bombardment gas comprises argon (Ar). In some embodiments, the first transition is accomplished in less than 0.5 s. In various embodiments, the first transition is accomplished in the range of 1 ms to 500 ms. In some embodiments, the first transition is accomplished in the range of 0.2 s to 0.5 s.

After the first transition (step 114), a removal step is provided (step 116). In some embodiments, the bombardment gas is provided at a pressure of about 20 mTorr. In various embodiments, the pressure is 1 mTorr to 25 mTorr. In some embodiments, the pressure of the modification gas is at least 10 mTorr more than the pressure of the bombardment gas. In some embodiments, the bombardment gas can be transformed into a plasma by providing more than 500 Watts of RF power at 13.56 MHz. In some embodiments, a bias is in the range of 200 eV to 2000 eV. In various embodiments, the bias is greater than 700 eV. In some embodiments, the bias voltage during the removal step is at least 10 times the bias voltage during the modification step. In some embodiments, this removal step (step 116) is provided for less than 0.5 s. In some embodiments, the removal step is provided for a time between 10 ms to 600 ms. In other embodiments, the removal step is provided for a time between 10 ms and 300 ms. In other embodiments, the removal step is provided for a time between 10 ms and 50 ms. In some embodiments, the removal step is provided for a time of less than 25 ms. In some embodiments, the bias power is provided as a continuous wave. In embodiments with a continuous wave, the removal step (step 116) may be for 20 ms in some examples. In some embodiments, the bias power may be pulsed. In pulsed embodiments, an exemplary pulsed RF bias power may be provided at a pulsed frequency of 100 Hz, the RF bias power has a 10% duty cycle during the removal step. In such pulsed embodiments with a 10% duty cycle, the removal step (step 116) is about 200 ms. In various embodiments, the pulsed bias has a duty cycle between 10% and 100%. In other embodiments, the pulsed bias has a duty cycle between 40% and 100%. A continuous wave bias for 20 ms can provide the same results as a pulsed bias at a 10% duty cycle for 200 ms if other parameters are the same. Therefore, an embodiment using a continuous bias during the removal step (step 116) for 20 ms can provide the same removal as a pulsed bias process with a 10% duty cycle for 200 ms. In order to provide a short removal step, bias ramping times must be short. In some embodiments, the bias may be ramped in less than 100 ms. In some embodiments, the bias can be ramped 0.1 ms to 10 ms. In some embodiments, the flux of bombardment ions near the modified layer is greater than 10¹⁷ ions/cm²s. In some embodiments, the flux of the ions is between about 10¹⁷ to 10²¹ ions/cm²s. The higher flux and higher energy ion bombardment reduces the time needed for the removal step.

FIG. 2C is a schematic cross-sectional view of a wafer 204 under the etch layer 208 disposed below the mask 212 after the removal step (step 116). The modified portion has been removed. FIG. 3C is a schematic view of an enlarged section of an exposed portion of the etch layer 208 during the removal step. Ions 312 bombard the etch layer causing modified atoms 304 bound with neutral radical atoms 308 to be removed.

After the removal step (step 116), a second transition is provided (step 118). The second transition removes the bombardment gas and provides the modification gas. In some embodiments, the second transition is accomplished less than 0.5 s. In various embodiments, the second transition is accomplished in the range of 1 ms to 500 ms. In some embodiments, the first transition is accomplished in the range of 0.2 s to 0.5 s.

The cycle of the steps of modification (step 112), first transition (step 114), removal (step 116), and second transition (step 118) is repeated a plurality of times until features are etched to a desired depth. In some embodiments, 70 Å is etched at each cycle.

Some embodiments are able to increase etch speeds by more than ten times over prior art ALE processes. The use of one or more of neutral radicals, faster transition times, the use of continuous wave or high duty cycle bias, and/or a greater ion flux during bombardment enable such faster embodiments. In an example, each cycle is about could be less than 35 ms. In some embodiments, each cycle is between about 20 ms and 1500 ms. In other embodiments, each cycle is between about 30 ms and 1000 ms.

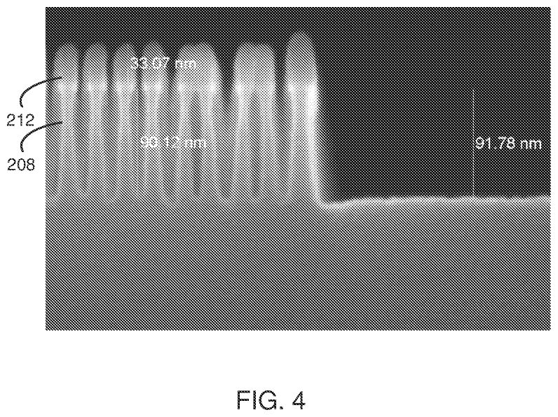

FIG. 4 is a cross-sectional side view of an etch layer 208 that has been etched according to some embodiments. It should be noted that the depth of the narrow features is about equal to the depth of the wide features. In addition, the bottom of the wide feature is relatively flat. In addition, much of the patterned photoresist mask 212 remains, indicating that the etch is highly selective.

It has been found that the combination of using neutral radicals, with a high flux and low bias provides a monolayer in less than 0.5 s. The time for absorption of the neutral radicals in forming the monolayer may be modeled accordingly in the relationship:

$$t \sim ( 1 - {e}^{- {k}_{N} {J}_{N} t} ) . \qquad ( 1 )$$

This relationship shows how time t is related to a reaction coefficient for the neutral radical (kw) and neutral radical flux (J_{N}). In some embodiments, the coefficient for neutral radicals is greater than the coefficient for ions. Some embodiments may have a flux of neutral radicals in the range between about 10¹⁷ to 10²¹ neutral radicals/cm²s.

It has been found that the combination of using higher energy ions and a high flux allows the removal of the modified monolayer in less than a second. The time for removing the modified layer may be modeled according to the relationship:

$$t \sim ( 1 - {e}^{- {kJ}_{i} {Y}_{i} t} ) . \qquad ( 2 )$$

This relationship shows how time t is related to the ion yield (Yᵢ) and the ion flux (Jᵢ). The ion yield Yᵢ is a function of ion energy, according to the relationship Y(ε)˜\sqrt{εᵢ}−\sqrt{εₜₕ}. Some embodiments have an ion flux in the range of between about 10¹⁷ to 10²¹ ions/cm²s. Some embodiments provide a bias in the range of 200 eV to 2000 eV in order to provide a desired ion energy.

In various embodiments, the modification gas is chlorine gas (Cl₂), and the neutral radicals are chlorine neutral radicals. When the modification gas is chlorine gas, in some embodiments, the etch layer is a silicon etch layer. The silicon etch layer may be a doped silicon. In other embodiments, the etch layer may be other silicon containing etch layers, such as silicon germanium (SiGe), silicon nitride (SiN), or silicon oxide (SiO₂). In other embodiments, the etch layer may be a metal etch layer. The metal etch layer may be ruthenium (Ru), molybdenum (Mo), tungsten (W), tantalum (Ta), or titanium (Ti). In other embodiments, the etch layer may be a metal containing etch layer, such as titanium nitride (TiN) or tantalum nitride (TaN). In other embodiments, the etch layer may be a metalloid or metalloid containing layer, such as a germanium (Ge) or germanium containing layer.

In other embodiments, the modification gas is an oxygen containing gas and the radical neutrals are oxygen atoms. In such embodiments, the mask may be SiO₂ or SiN When the modification gas is an oxygen containing gas, the etch layer may be a carbon containing layer, such as an amorphous carbon layer that has some hydrogen or pure carbon, or a ruthenium containing layer. In various embodiments, the oxygen containing gas is oxygen gas (O₂), carbon dioxide (CO₂), carbon monoxide (CO), sulfur dioxide (SO₂), and water (H₂O). In various embodiments, the modification gas consists essentially of chlorine gas or an oxygen containing gas. In various embodiments, the bombardment gas may comprise Ar, helium (He), neon (Ne), krypton (Kr), and xenon (Xe). In some embodiments, the bombardment gas consists essentially of one or more of Ar, He, Ne, Kr, and Xe. For example, Ar+ bombardment ions can be generated from Ar bombardment gas.

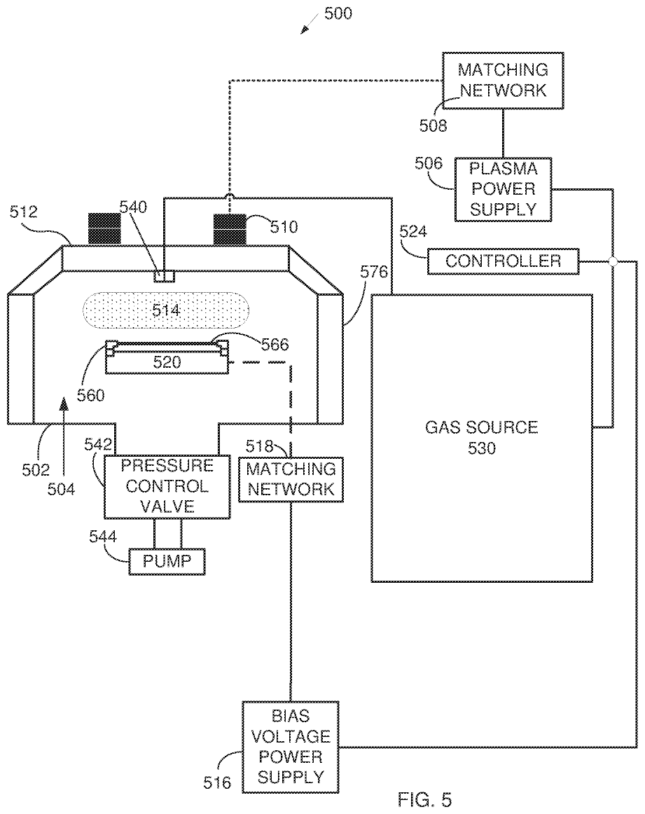

To provide an embodiment of a processing chamber that may be used in some embodiments, FIG. 5 schematically illustrates an example of a plasma processing chamber system 500 that may be used for the plasma processing process. The plasma processing chamber system 500 includes a plasma reactor 502 having a plasma processing confinement chamber 504 therein. A plasma power supply 506, tuned by a plasma matching network 508, supplies power to a transformer coupled plasma (TCP) coil 510 located near a dielectric inductive power window 512 to create a plasma 514 in the plasma processing confinement chamber 504 by providing an inductively coupled power.

The TCP coil (upper power source) 510 may be configured to produce a uniform diffusion profile within the plasma processing confinement chamber 504. For example, the TCP coil 510 may be configured to generate a toroidal power distribution in the plasma 514. The dielectric inductive power window 512 is provided to separate the TCP coil 510 from the plasma processing confinement chamber 504 while allowing energy to pass from the TCP coil 510 to the plasma processing confinement chamber 504. The TCP coil 510 acts as an electrode for providing radio frequency (RF) power to the plasma processing confinement chamber 504. A wafer bias voltage power supply 516 tuned by a bias matching network 518 provides power to an electrode 520 to set the bias voltage on the substrate 566. The substrate 566 is supported by the electrode 520 so that the electrode acts as a substrate support. A controller 524 controls the plasma power supply 506 and the wafer bias voltage power supply 516.

The plasma power supply 506 and the wafer bias voltage power supply 516 may be configured to operate at specific radio frequencies such as, for example, 13.56 megahertz (MHz), 27 MHz, 2 MHz, 60 MHz, 400 kilohertz (kHz), 2.54 gigahertz (GHz), or combinations thereof. Plasma power supply 506 and wafer bias voltage power supply 516 may be appropriately sized to supply a range of powers in order to achieve the desired process performance. For example, in some embodiments, the plasma power supply 506 may supply power in a range of 50 to 5000 Watts, and the wafer bias voltage power supply 516 may supply a bias voltage in a range of 20 to 2000 V. In addition, the TCP coil 510 and/or the electrode 520 may be comprised of two or more sub-coils or sub-electrodes. The sub-coils or sub-electrodes may be powered by a single power supply or powered by multiple power supplies.

As shown in FIG. 5, the plasma processing chamber system 500 further includes a gas source/gas supply mechanism 530. The gas source 530 is in fluid connection with plasma processing confinement chamber 504 through a gas inlet, such as a gas injector 540. The gas injector 540 may be located in any advantageous location in the plasma processing confinement chamber 504 and may take any form for injecting gas. Preferably, however, the gas inlet may be configured to produce a “tunable” gas injection profile. The tunable gas injection profile allows independent adjustment of the respective flow of the gases to multiple zones in the plasma process confinement chamber 504. More preferably, the gas injector is mounted to the dielectric inductive power window 512. The gas injector may be mounted on, mounted in, or form part of the power window. The process gases and by-products are removed from the plasma process confinement chamber 504 via a pressure control valve 542 and a pump 544. The pressure control valve 542 and pump 544 also serve to maintain a particular pressure within the plasma processing confinement chamber 504. The pressure control valve 542 can maintain a pressure of less than 1 torr during processing. An edge ring 560 is placed around the substrate 566. The gas source/gas supply mechanism 530 is controlled by the controller 524. An example of such a plasma processing chamber system 500 is described in PCT application PCT/US21/31490, entitled Distributed Plasma Source Array, filed on May 10, 2021, which is incorporated by reference for all purposes. An example of such a plasma processing chamber is the Syndion® etch system manufactured by Lam Research Corporation of Fremont, CA.

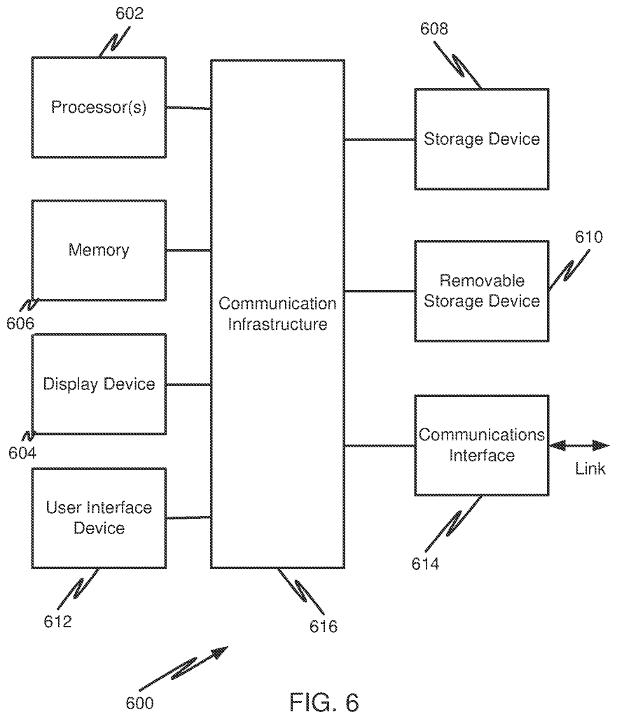

FIG. 6 is a high level block diagram showing a computer system 600. The computer system 600 is suitable for implementing a controller 524 used in embodiments. The computer system 600 may have many physical forms ranging from an integrated circuit, a printed circuit board, and a small handheld device up to a huge supercomputer. The computer system 600 includes one or more processors 602, and further can include an electronic display device 604 (for displaying graphics, text, and other data), a main memory 606 (e.g., random access memory (RAM)), storage device 608 (e.g., hard disk drive), removable storage device 610 (e.g., optical disk drive), user interface devices 612 (e.g., keyboards, touch screens, keypads, mice or other pointing devices, etc.), and a communications interface 614 (e.g., wireless network interface). The communications interface 614 allows software and data to be transferred between the computer system 600 and external devices via a link. The system may also include a communications infrastructure 616 (e.g., a communications bus, cross-over bar, or network) to which the aforementioned devices/modules are connected.

Information transferred via communications interface 614 may be in the form of signals such as electronic, electromagnetic, optical, or other signals capable of being received by communications interface 614, via a communications link that carries signals and may be implemented using wire or cable, fiber optics, a phone line, a cellular phone link, a radio frequency link, and/or other communications channels. With such a communications interface 614, it is contemplated that the one or more processors 602 might receive information from a network, or might output information to the network in the course of performing the above-described method steps. Furthermore, method embodiments may execute solely upon the processors or may execute over a network such as the Internet, in conjunction with remote processors that share a portion of the processing.

The term “non-transient computer readable medium” is used generally to refer to media such as main memory, secondary memory, removable storage, and storage devices, such as hard disks, flash memory, disk drive memory, CD-ROM, and other forms of persistent memory and shall not be construed to cover transitory subject matter, such as carrier waves or signals. Examples of computer readable code include machine code, such as produced by a compiler, and files containing higher level code that are executed by a computer using an interpreter. Computer readable media may also be computer code transmitted by a computer data signal to a processor.

In some embodiments, the computer readable media may comprise computer readable code for providing a modification step for less than 0.5 seconds (step 112), computer readable code for providing a first transition from the modification gas to the bombardment gas in less than 0.5 seconds (step 114), computer readable code for providing a removal step for less than 0.5 seconds (step 116), and computer readable code for providing a second transition from the bombardment gas to the modification gas in less than 0.5 seconds (step 118).

In other embodiments, instead of forming the plasma in the reactor where the substrate is located, for the modification step, the plasma may be formed remotely. Radical neutrals may be provided by the remote plasma source. In some embodiments, charged ions are prevented from entering the reactor during the modification step.

While this disclosure has been described in terms of several preferred embodiments, there are alterations, modifications, permutations, and various substitute equivalents, which fall within the scope of this disclosure. It should also be noted that there are many alternative ways of implementing the methods and apparatuses of the present disclosure. It is therefore intended that the following appended claims be interpreted as including all such alterations, modifications, permutations, and various substitute equivalents as fall within the true spirit and scope of the present disclosure.

What is claimed is:

1. A method for etching an etch layer, the method comprising a plurality of cycles, wherein each cycle, comprises:
exposing the etch layer to neutral radicals for a time between 10 ms and 600 ms, wherein the neutral radicals are absorbed into the etch layer to form a modified part of the etch layer; and
exposing the etch layer to bombardment ions for a time between 10 ms and 600 ms, wherein the bombardment ions remove the modified part of the etch layer.

2. The method, as recited in claim 1, wherein the exposing the etch layer to bombardment ions provides a bias of greater than 700 eV.

3. The method, as recited in claim 1, wherein the neutral radicals have a flux of greater than 10¹⁷ neutral radicals/cm²s.

4. The method, as recited in claim 1, wherein the bombardment ions have a flux of greater than 10¹⁷ ions/cm²s.

5. The method, as recited in claim 1, wherein the exposing the etch layer to bombarding ions is for a time between 10 ms and 250 ms.

6. The method of claim 1, wherein the exposing the etch layer to bombarding ions is for a time between 10 ms and 25 ms.

7. The method, as recited in claim 1, wherein the exposing the etch layer to bombarding ions comprises providing a bias in a range of 200 eV to 2000 eV.

8. The method, as recited in claim 7, wherein the bias is a continuous wave bias.

9. The method, as recited in claim 7, wherein the bias is a pulsed bias.

10. The method, as recited in claim 7, wherein the bias is ramped up in less than 100 ms.

11. The method, as recited in claim 1, further comprising:
providing a first transition from a modification gas to a bombardment gas in less than 0.5 seconds, wherein the modification gas transformed to provide the neutral radicals the bombardment gas is transformed into bombardment ions, and wherein the first transition is after the exposing the etch layer to neutral radicals and before exposing the etch layer to bombardment ions; and
providing a second transition from the bombardment gas to the modification gas, wherein the second transition is after the exposing the etch layer to the bombardment ions and before exposing the etch layer to neutral radicals.

12. The method, as recited in claim 1, wherein the neutral radicals are chloride atoms or oxygen atoms.

13. The method, as recited in claim 1, wherein the bombardment ions are ions of argon, helium, neon, krypton, and xenon.

14. The method, as recited in claim 1, wherein the exposing the etch layer to bombardment ions comprises providing an RF power of more than 2000 W.

15. An etching system for etching an etch layer over a substrate, the etching system, comprising:
a processing chamber;
a substrate support for supporting a substrate in the processing chamber;
an RF power source for providing RF power to etch chamber;
a neutral radical source adapted to provide neutral radicals in the processing chamber;
a bombardment gas source adapted to provide bombardment gas in the processing chamber;
a controller controllably connected to the RF power source, the neutral radical source, and the bombardment gas source, configured to:
a) expose the etch layer to neutral radicals for a time between 10 ms and 600 ms, wherein the neutral radicals are absorbed into the etch layer to form a modified part of the etch layer; and
b) expose the etch layer to bombardment ions for a time between 10 ms and 600 ms, wherein the bombardment ions remove the modified part of the etch layer.

16. The etching system, as recited in claim 15, wherein the exposing the etch layer to bombardment ions provides a bias of greater than 700 eV.

17. The etching system, recited in claim 15, wherein the neutral radicals have a flux of greater than 10¹⁷ neutral radicals/cm²s.

18. The etching system, as recited in claim 15, wherein the bombardment ions have a flux of greater than 10¹⁷ ions/cm²s.

19. The etching system, as recited in claim 15, wherein the exposing the etch layer to bombarding ions comprises providing a bias in a range of 200 eV to 2000 eV.

20. The etching system, as recited in claim 19, wherein the bias is a continuous wave bias.

21. The etching system, as recited in claim 19, wherein the bias is a pulsed bias.

22. The etching system, as recited in claim 19, wherein the bias is ramped up in less than 100 ms.

23. The etching system, as recited in claim 15, wherein the controller is further configured to:
provide a first transition from a modification gas to a bombardment gas in less than 0.5 seconds, wherein the modification gas transformed to provide the neutral radicals the bombardment gas is transformed into bombardment ions, and wherein the first transition is after the exposing the etch layer to neutral radicals and before exposing the etch layer to bombardment ions; and
provide a second transition from the bombardment gas to the modification gas, wherein the second transition is after the exposing the etch layer to the bombardment ions and before exposing the etch layer to neutral radicals.

24. The etching system, as recited in claim 15, wherein the exposing the etch layer to bombardment ions comprises providing an RF power of more than 2000 W.
